(19) United States
(12) Patent Application Publication
(10) Pub. No.: US 2020/0159059 A1
(43) Pub. Date: May 21, 2020

(54) DISPLAY DEVICE AND MANUFACTURING METHOD

(71) Applicant: SHARP KABUSHIKI KAISHA, Sakai City, Osaka (JP)

(72) Inventor: YASUSHI TAKEDA, Sakai City, Osaka (JP)

(21) Appl. No.: 16/610,680

(22) PCT Filed: May 7, 2018
(86) PCT No.: PCT/JP2018/017654

§ 371 Date: Nov. 4, 2019

(30) Foreign Application Priority Data
May 12, 2017 (JP) 2017-096046

(51) Int. Cl. G02F 1/1345; G02F 1/1333; H05K 1/18; H05K 1/14

(52) U.S. Cl. CPC G02F 1/13452; G02F 1/133308; H05K 1/189; H05K 2201/09036; H05K 2201/10136; H05K 2201/10189; H05K 1/147

(57) ABSTRACT

A thickness of a space necessary for arrangement of a circuit substrate is able to be reduced. A circuit substrate (6) provided with a notch portion (66) is attached to a liquid crystal display panel (2) through a bezel (4) and a stay (5). An overlapping portion (52) of the stay (5) includes a fitting portion (54) capable of being fitted into an inside of the notch portion (66) and is able to be engaged with the circuit substrate (6).

### TECHNICAL FIELD

The present invention relates to a display device and a manufacturing method of the display device. The invention particularly relates to a display device in which a circuit substrate is attached to a display panel and a manufacturing method of the display device.

### BACKGROUND ART

In many display devices, a control circuit that controls a display panel is provided in a circuit substrate separate from the display panel. According to such a configuration, the circuit substrate is movable relatively to the display panel and a mechanical load is applied to a wire by which the circuit substrate is connected to the display panel, thus posing a problem that a display device breaks down.

Thus, in recent years, in order to prevent the breakdown, the circuit substrate has been fixedly attached to the display panel through a holder so as not to apply the mechanical load to the wire.

For example, PTL 1 discloses (i) examination related to a mechanical load applied to a wire when a mechanical force is applied to a connector on a circuit substrate in a direction vertical to a display screen and (ii) some configurations to prevent release, in which the circuit substrate is fixedly attached to a display panel through a holder. In addition, PTL 2 also discloses some configurations in which a circuit substrate is fixedly attached to a display panel through a holder.

### CITATION LIST

### Patent Literature

PTL 1: Japanese Unexamined Patent Application Publication No. 10-288948 (published on Oct. 27, 1998)

PTL 2: Japanese Unexamined Patent Application Publication No. 2013-135435 (published on Jul. 8, 2013)

### SUMMARY OF INVENTION

### Technical Problem

However, conventional techniques as described above have a problem that, since a thickness of overlap of the holder and the circuit substrate is larger than a thickness of only the circuit substrate, a thickness of a space necessary for arrangement of the circuit substrate increases.

An aspect of the invention aims to realize a display device capable of reducing a thickness of a space necessary for arrangement of a circuit substrate and a manufacturing method of the display device.

### Solution to Problem

In order to solve the aforementioned problem, a display device according to an aspect of the invention includes: a display panel provided with a display screen; a circuit substrate provided with a notch portion; a wiring portion that connects the circuit substrate with the display panel; and a holding structure by which the circuit substrate is attached to the display panel, in which the holding structure includes a first engagement portion that includes a fitting portion capable of being fitted into an inside of the notch portion and is able to be engaged with the circuit substrate, and a second engagement portion that is different from the first engagement portion and is able to be engaged with the display panel.

In order to solve the aforementioned problem, a manufacturing method of a display device according to an aspect of the invention includes the steps of: connecting a circuit substrate, which is provided with a notch portion, with a display panel, which is provided with a display screen, through a wiring portion; and attaching the circuit substrate to the display panel through the holding structure, in which the attaching includes causing a fitting portion provided in a first engagement portion of the holding structure to be fitted into an inside of the notch portion and causing the first engagement portion to be engaged with the circuit substrate; and causing a second engagement portion, which is different form the first engagement portion of the holding structure, to be engaged with the display panel.

### Advantageous Effects of Invention

According to an aspect of the invention, an effect by which a thickness of a space necessary for arrangement of a circuit substrate is able to be reduced is exerted.

### BRIEF DESCRIPTION OF DRAWINGS

FIG. 1 is a sectional view illustrating a schematic configuration of an end of a liquid crystal display module according to an embodiment of the invention.

FIG. 2 is a top view illustrating the schematic configuration of the end of the liquid crystal display module illustrated in FIG. 1.

FIG. 3 is a bottom view illustrating the schematic configuration of the end of the liquid crystal display module illustrated in FIG. 1.

FIG. 4 illustrates a schematic configuration of a substrate illustrated in FIG. 1, in which FIG. 4(a) is a top view, FIG. 4(b) is a bottom view, and FIG. 4(c) is a sectional view.

FIG. 5 illustrates a schematic configuration of a stay illustrated in FIG. 1, in which FIG. 5(a) is a sectional view and FIG. 5(b) is a bottom view.

FIG. 6 is a view for explaining a process of cutting out the stay from a bezel.

FIG. 7 is a view for explaining the process of cutting out the stay from the bezel.

FIG. 8(a) is a sectional view illustrating the substrate and the stay that are illustrated in FIG. 1 and FIG. 8(b) is a sectional view illustrating a substrate and a stay that are illustrated in FIG. 15, and FIGS. 8(a) and 8(b) are views for comparing both of them.

FIG. 9 is a sectional view illustrating a schematic configuration of an end of a liquid crystal display module according to another embodiment of the invention.

FIG. 10(a) is a sectional view illustrating the substrate and the stay that are illustrated in FIG. 1 and FIG. 10(b) is a sectional view illustrating a substrate and a stay that are illustrated in FIG. 9, and FIGS. 10(a) and 10(b) are views for comparing both of them.

FIG. 11 is a top view illustrating a schematic configuration of an end of a liquid crystal display module according to still another embodiment of the invention.

FIG. 12 is a bottom view illustrating the schematic configuration of the end of the liquid crystal display module illustrated in FIG. 11.

FIG. 13 is a sectional view illustrating a schematic configuration of an end of a liquid crystal display module according to still another embodiment of the invention.

FIG. 14 is a perspective view illustrating a schematic configuration of a corner of the liquid crystal display module illustrated in FIG. 13.

FIG. 15 is a sectional view illustrating a schematic configuration of an end of a liquid crystal display module as a comparative example.

### DESCRIPTION OF EMBODIMENTS

### Embodiment 1

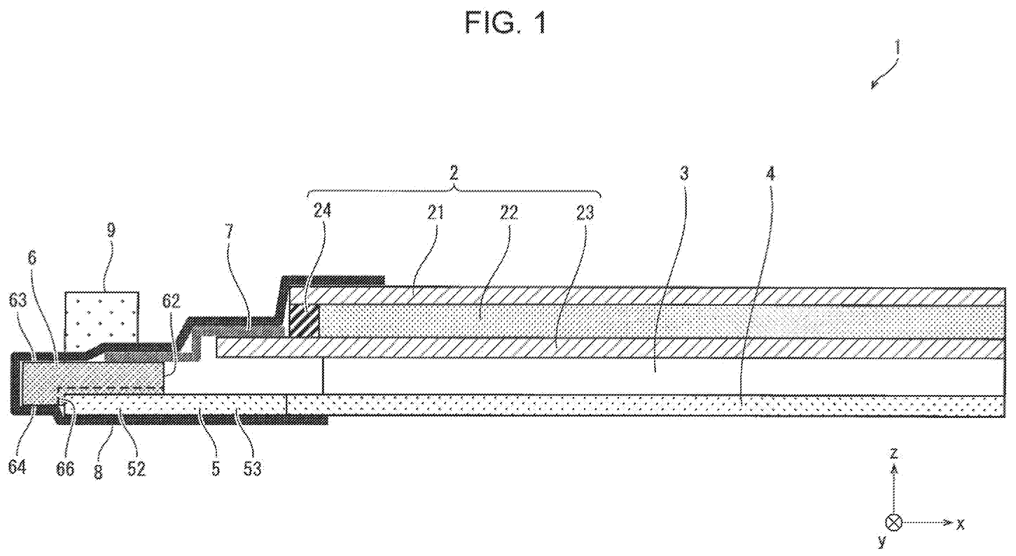

An exemplary embodiment of the invention will be specifically described below with reference to FIGS. 1 to 8.

### (Liquid Crystal Display Module)

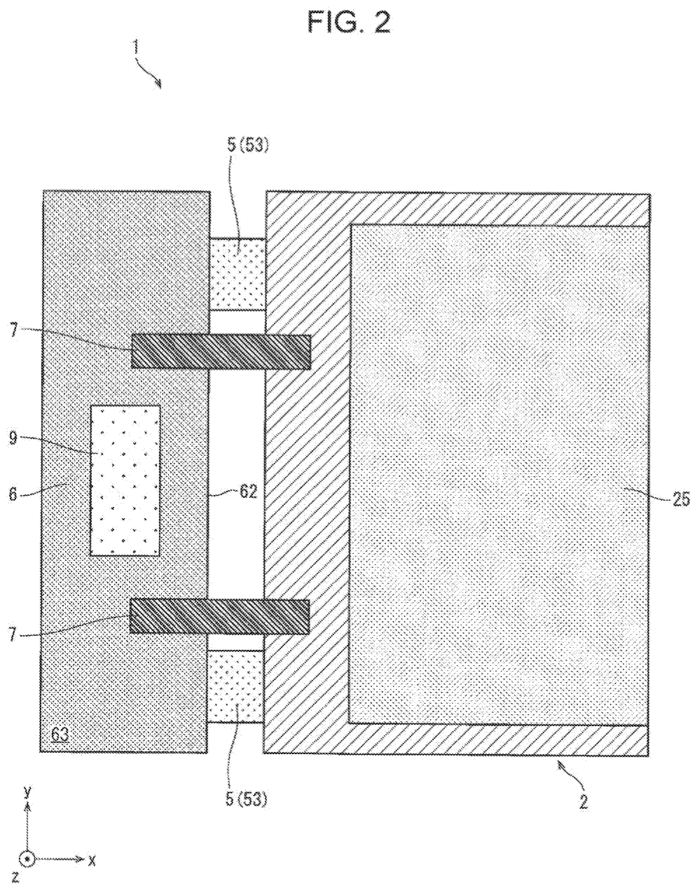

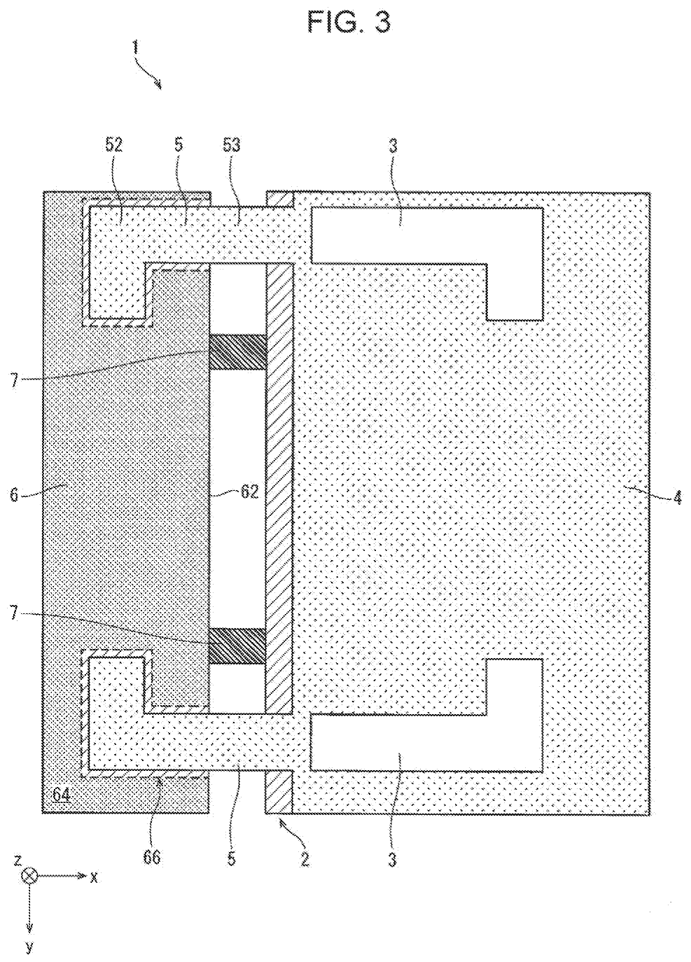

FIG. 1 is a sectional view illustrating a schematic configuration of an end of a liquid crystal display module 1 (display device) according to Embodiment 1 of the invention. FIG. 2 is a top view illustrating the schematic configuration of the end of the liquid crystal display module 1 illustrated in FIG. 1. FIG. 3 is a bottom view illustrating the schematic configuration of the end of the liquid crystal display module 1 illustrated in FIG. 1. Note that, for convenience of illustration, protection tape 8 is omitted in FIGS. 2 and 3.

### (Liquid Crystal Display Panel)

As illustrated in FIGS. 1 to 3, the liquid crystal display module 1 includes a liquid crystal display panel 2 (display panel).

The liquid crystal display panel 2 includes a display screen 25 capable of displaying an image (a still image and a moving image). The liquid crystal display panel 2 includes a facing substrate 21, a matrix substrate 23, liquid crystal 22 between the facing substrate 21 and the matrix substrate 23, and a sealant 24 that seals the liquid crystal 22.

The liquid crystal display panel 2 according to Embodiment 1 is of a transmission type, but is not limited thereto and may be of a reflection type. A specific configuration of the liquid crystal display panel 2 may be any known configuration and detailed description thereof will be omitted.

In the present specification and attached drawings, an xyz orthogonal coordinate system defined as follows is used.

x axis: direction parallel to the display screen 25
y axis: direction parallel to the display screen 25 and orthogonal to the x axis
z axis: direction orthogonal to the display screen 25

### (Backlight)

The liquid crystal display module 1 includes a backlight 3 as illustrated in FIGS. 1 to 3.

The backlight 3 is arranged on a back surface side (that is, −z direction side) of the liquid crystal display panel 2 so as not to be changed in position relative to the liquid crystal display panel 2.

The backlight 3 according to Embodiment 1 is a so-called surface light emitting apparatus of a side surface type that includes a light guide plate and a linear light source arranged in a side surface of the light guide plate. The linear light source is, for example, a fluorescent tube or a light emitting diode that is arranged linearly. Note that, the backlight 3 is not limited thereto and may be a so-called surface light emitting apparatus of a direct type that includes a diffuser plate and a plurality of point light sources arranged directly below the diffuser plate. Alternatively, in a case where the liquid crystal display panel 2 is of a reflection type, the backlight 3 may not be arranged. A specific configuration of the backlight 3 may be any known configuration and detailed description thereof will be omitted.

### (Bezel)

As illustrated in FIGS. 1 to 3, the liquid crystal display module 1 includes a backlight rear bezel 4 (hereinafter, referred to as a “bezel 4”) (holding structure, second engagement portion).

The bezel 4 is arranged on a back surface side (that is, −z direction side) of the backlight 3 so as not to be changed in position relative to the liquid crystal display panel 2 and the backlight 3. Thus, the backlight 3 is held between the bezel 4 and the liquid crystal display panel 2.

The bezel 4 supports the backlight 3. For example, in a case where the backlight 3 is the surface light emitting apparatus of the side surface type, the bezel 4 preferably supports the light guide plate of the backlight 3 and also functions as a reflection plate that returns light to the light guide plate. The bezel 4 is normally formed by metal, and is thus usable also as a conductor that transmits electricity and/or heat. For example, the bezel 4 may be used also as a ground conductor and a heat radiation path.

### (Circuit Substrate)

As illustrated in FIGS. 1 to 3, the liquid crystal display module 1 includes a circuit substrate 6.

The circuit substrate 6 is a rigid substrate on which a connector 9 is mounted. Though not illustrated in FIGS. 1 to 3, a control circuit or the like that controls the liquid crystal display panel 2 may be formed on the circuit substrate 6.

The circuit substrate 6 is arranged at a position in a −x direction relatively in parallel to the liquid crystal display panel 2. Specifically, a side surface 62 of the circuit substrate 6, which faces in a +x direction, is opposed to a side surface of the liquid crystal display panel 2, which faces in the −x direction, in parallel, and an upper surface 63 and a lower surface 64 of the circuit substrate 6, which respectively faces in a +z direction and a −z direction, are parallel to the display screen 25. Note that, it is also possible that the circuit substrate 6 is arranged diagonally to the liquid crystal display panel 2 or arranged above or below the liquid crystal display panel 2. However, from a viewpoint of reduction in thickness and size of the liquid crystal display module 1 and a viewpoint of reduction in wiring distance, it is normally preferable that the circuit substrate 6 is arranged at a side position relatively in parallel to the liquid crystal display panel 2.

The connector 9 is an interface that connects the control circuit on the circuit substrate 6 and/or the liquid crystal display panel 2 with an outside of the liquid crystal display module 1 in a wired manner. When a cable or the like by which a signal and/or power are/is supplied is inserted into or removed from the connector 9, a mechanical force is applied to the connector 9. Moreover, while the cable or the like is attached to the connector 9, a mechanical force is applied to the connector 9 through the attached cable or the like in some cases.

The connector 9 may be inserted or removed in any direction, but is preferably inserted or removed in an x axis direction. When the connector 9 is inserted or removed in the x axis direction, a mechanical force caused by the insertion/removal acts in the x axis direction. Thus, since the direction of the force is parallel to a direction of the circuit substrate 6 as viewed from the liquid crystal display panel 2, a shearing force acting on a stay 5 described later is able to be reduced, so that the insertion/removal in the x axis direction is preferable.

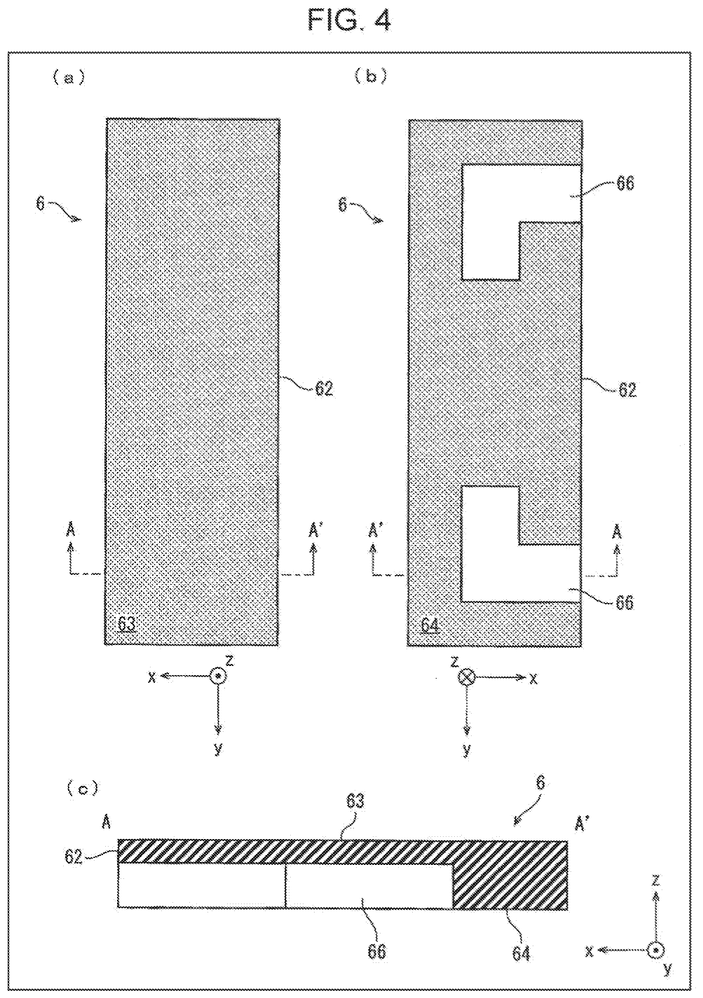

FIG. 4 illustrates a schematic configuration of the circuit substrate 6 illustrated in FIG. 1, in which FIG. 4(a) is a top view, FIG. 4(b) is a bottom view, and FIG. 4(c) is a sectional view taken along a line A-A′.

As illustrated in FIGS. 3 and 4, in the circuit substrate 6, an L-shape is cut out from the lower surface 64 and a notch portion 66 of the L-shape is provided. The shape of the notch portion 66 is not limited to the L-shape, may be an I-shape or a T-shape, or may be any shape as long as allowing communication with any side surface of the circuit substrate 6. The shape of the notch portion 66 is preferably a shape that enables communication with the side surface 62 of the circuit substrate 6, which is opposed to the liquid crystal display panel 2, and is preferably a shape that enables meshing with a fitting portion 54 of the stay 5 described later. Specifically, for example, a shape, such as an L-shape or a T-shape, a vertical bar portion of which is connected to the side surface 62 is preferable.

Note that, though the circuit substrate 6 that is cut out from the lower surface 64 is exemplified in Embodiment 1, the circuit substrate 6 may be cut out from the upper surface 63 or may be penetrated between the upper surface 63 and the lower surface 64 as in Embodiment 3 described later.

### (Flexible Substrate)

As illustrated in FIGS. 1 to 3, the liquid crystal display module 1 includes a flexible substrate 7 (wiring portion).

The flexible substrate 7 is exemplified as the wiring portion that connects the circuit substrate 6 with the liquid crystal display panel 2. The liquid crystal display module 1 may not include the flexible substrate 7 and may include a wiring portion of another type, for example, a coated wire.

### (Stay)

As illustrated in FIGS. 1 to 3, the liquid crystal display module 1 includes the stay 5 (holding structure).

The stay 5 is formed integrally with the bezel 4 and is able to function, in cooperation with the bezel 4, as the holding structure by which the circuit substrate 6 is able to be fixedly attached to the liquid crystal display panel 2. Note that, without limitation to being attached to the liquid crystal display panel 2 through the stay 5, the circuit substrate 6 may be attached to an exterior of the liquid crystal display module 1 through another structure, that is, without using the stay 5, the bezel 4, the backlight 3, or the liquid crystal display panel 2. Further, the stay 5 may function as a ground conductor similarly to the bezel 4.

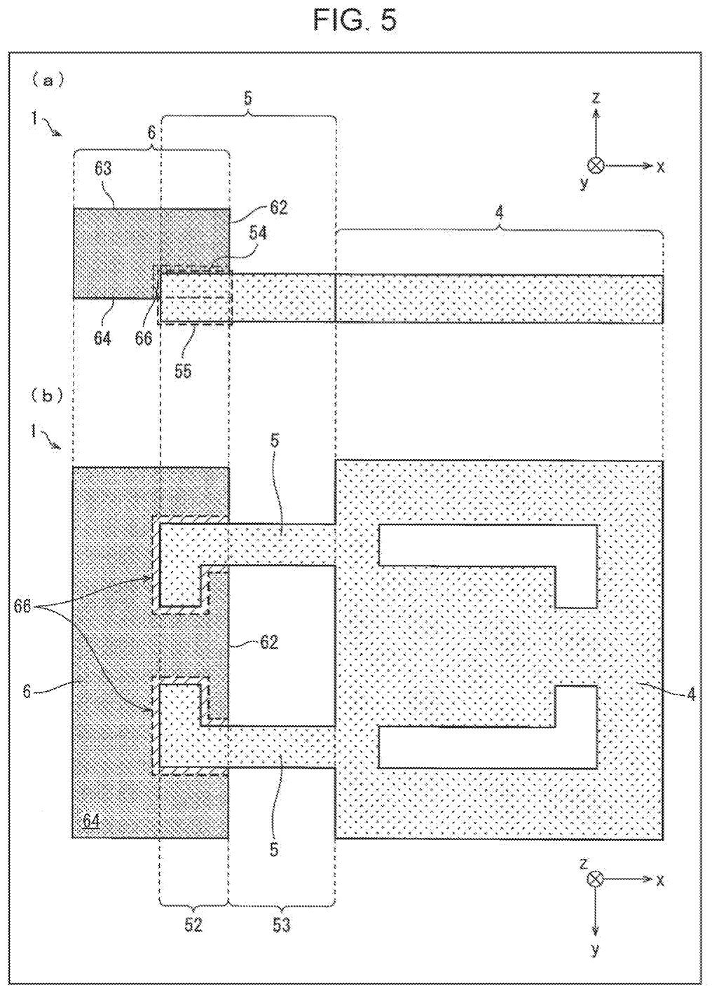

FIG. 5 illustrates a schematic configuration of the stay 5 illustrated in FIG. 1, in which FIG. 5(a) is a sectional view and FIG. 5(b) is a bottom view.

As illustrated in FIGS. 3 and 5, the stay 5 in Embodiment 1 is formed as a part of the bezel 4. The bezel 4 is indirectly attached to the liquid crystal display panel 2 through the backlight 3 and is not changed in position relative to the liquid crystal display panel 2. Thus, the stay 5 is able to be engaged with the liquid crystal display panel 2 through the bezel 4 and the backlight 3 indirectly and stably.

Note that, the stay 5 is not limited thereto and may be formed in any manner as long as being able to hold the circuit substrate 6 so that the position of the circuit substrate 6 relative to the liquid crystal display panel 2 is fixed. Specifically, the stay 5 may be formed in any manner as long as having sufficient stiffness for holding the circuit substrate 6, being able to be engaged with the circuit substrate 6 directly or indirectly and stably, and being able to be engaged with the liquid crystal display panel 2 directly or indirectly and stably. For example, the stay 5 may be formed separately from the bezel 4 so that the stay 5 is be able to function as the holding structure alone.

As illustrated in FIG. 5, an overlapping portion 52 of the stay 5 is overlapped with the circuit substrate 6 in plan view from a z axis direction. The overlapping portion 52 of the stay 5 includes the fitting portion 54 that is fitted into an inside of the notch portion 66. A shape of the fitting portion 54 is preferably a shape complementary to the notch portion 66 and is more preferably a shape that enables meshing. In addition, in some cases, the overlapping portion 52 of the stay 5 includes a non-fitting portion 55 that is not fitted into the inside of the notch portion 66. An outer circumference of the non-fitting portion 55 is preferably almost matched with an outer circumference of the fitting portion 54 in plan view from the z axis direction. The non-fitting portion 55 preferably has a shape that is able to be meshed with the notch portion 66.

As illustrated in FIG. 5, a connection portion 53 of the stay 5 connects the overlapping portion 52 with the bezel 4 and is not overlapped with the circuit substrate 6 in plan view from the z axis direction.

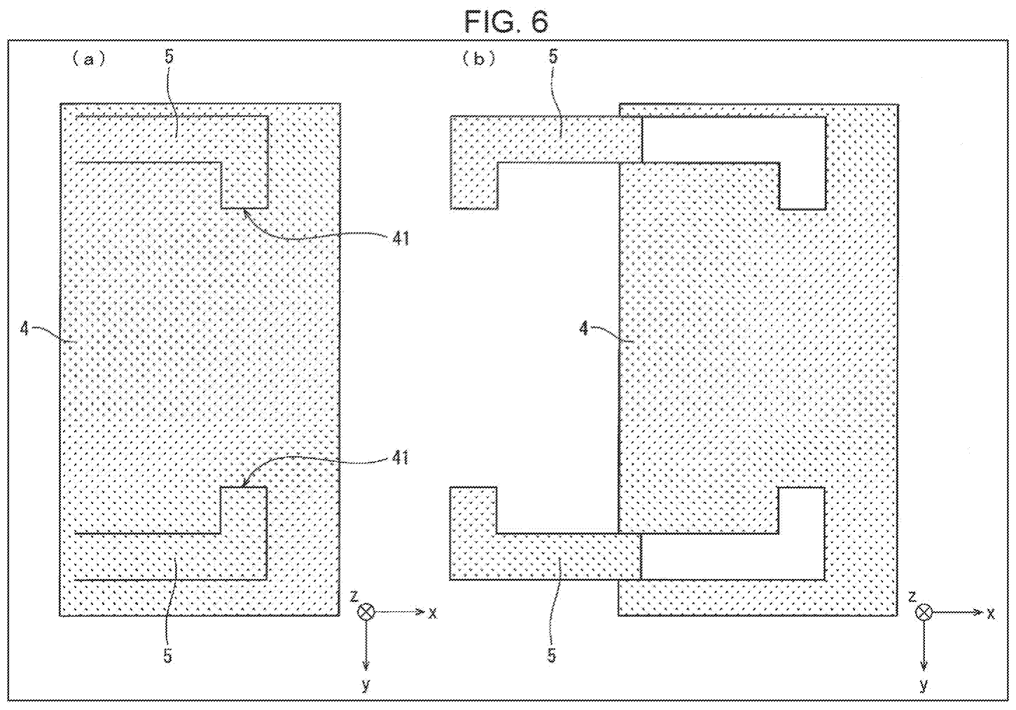

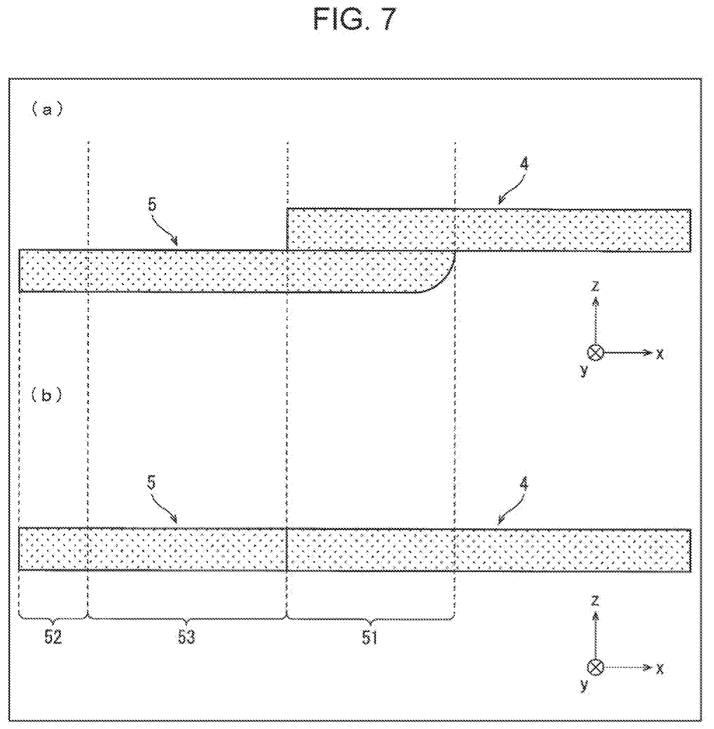

The stay 5 is formed as the part of the bezel 4 in various ways. For example, it is possible that a metal plate is embossed so that a projected portion extends from a main body portion, and the projected portion is used as the stay 5 and the main body portion is used as the bezel 4. Moreover, for example, as in FIGS. 6 and 7, it is also possible that a metal plate having no projected portion is used as the bezel 4 and the stay 5 is cut out from the bezel 4.

FIGS. 6 and 7 are views for explaining a process of cutting out the stay 5 from the bezel 4.

First, a slit 41 is cut on an end of the bezel 4 as illustrated in FIG. 6(a), and then, the stay 5 is rotated with a part connected to the bezel 4 as a center until being in an opposite direction compared to FIG. 6(a) as illustrated in FIG. 6(b).

At this stage, a root 51 of the stay 5 is protruded from the bezel 4 as illustrated in FIG. 7(a). Therefore, subsequently, the root 51 of the stay 5 is preferably crushed so that the bezel 4 and the stay 5 are flat as illustrated in FIG. 7(b).

(Protection tape)

As illustrated in FIG. 1, the liquid crystal display module 1 includes the protection tape 8.

The protection tape 8 is protection tape that protects a surface of the circuit substrate 6. In addition, the protection tape is adhesive tape that enables adhesion to the circuit substrate 6, the stay 5, the bezel 4, and the liquid crystal display panel 2 and is adhesive tape that enables adhesion also to the flexible substrate 7 in some cases. Though the protection tape 8 is adhesive tape, the protection tape 8 is only required to enable adhesion to a protection target, and is thus relatively weak adhesive tape, normally.

The protection tape 8 is put on at least surfaces of the stay 5 and the circuit substrate 6 and is thus able to stabilize fitting of the fitting portion 54 of the stay 5 and the notch portion 66 of the circuit substrate 6. Thus, adhesion by the protection tape 8 and such fitting enable the overlapping portion 52 of the stay 5 to be engaged with the circuit substrate 6 directly and stably.

### (Comparison)

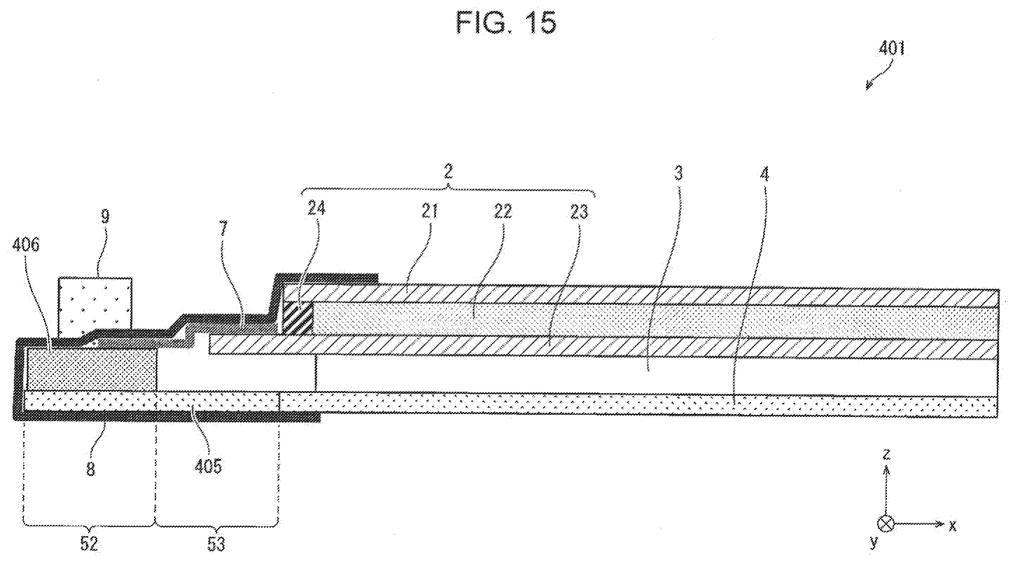

FIG. 15 is a sectional view illustrating a schematic configuration of an end of a liquid crystal display module 401 as a comparative example.

As illustrated in FIG. 15, the liquid crystal display module 401 as the comparative example includes the liquid crystal display panel 2, the backlight 3, the bezel 4, the flexile substrate 7, and the protection tape 8, similarly to the liquid crystal display module 1 according to Embodiment 1. The liquid crystal display module 401 as the comparative example is different from the liquid crystal display module 1 according to Embodiment 1 and includes a circuit substrate 406 in which no notch portion is provided and a stay 405 in which no fitting portion is provided.

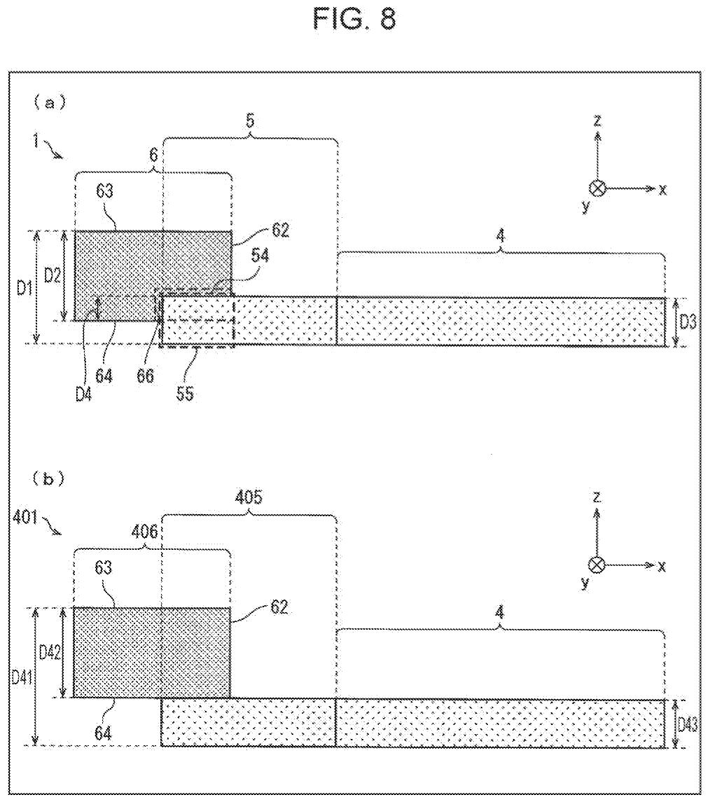

FIG. 8(a) is a sectional view illustrating the circuit substrate 6 and the stay 5 that are illustrated in FIG. 1 and FIG. 8(b) is a sectional view illustrating the circuit substrate 406 and the stay 405 that are illustrated in FIG. 15, and FIGS. 8(a) and 8(b) are views for comparing both of them.

As illustrated in FIG. 8(a), in the liquid crystal display module 1 according to Embodiment 1, the fitting portion 54 is fitted into the inside of the notch portion 66. Thus, a thickness D1 of overlap of the circuit substrate 6 and the overlapping portion 52 of the stay 5 is smaller than a sum of a thickness D2 of the circuit substrate 6 and a thickness D3 of the overlapping portion 52 of the stay 5. Further, the fitting portion 54 is meshed with the notch portion 66. Thus, since opposed surfaces of the fitting portion 54 and the notch portion 66 resist a force parallel to an xy plane, engagement of the circuit substrate 6 and the stay 5 is easily kept.

On the other hand, in the liquid crystal display module 401 as the comparative example, the circuit substrate 406 and the stay 405 are not fitted or meshed as illustrated in FIG. 8(b). Thus, a thickness D41 of overlap of the circuit substrate 406 and the overlapping portion 52 of the stay 405 is equal to a sum of a thickness D42 of a circuit and the circuit substrate 406 and a thickness D43 of the overlapping portion 52 of the stay 405. Further, since the protection tape 8 only resists the force parallel to the xy plane, the engagement of the circuit substrate 406 and the stay 405 is difficult to be kept. This is because, normally, the protection tape 8 is relatively weak adhesive tape. In other words, the protection tape 8 is not such strong adhesive tape that has strength and an adhesive force that enable to keep the engagement of the circuit substrate 406 and the stay 405 against the force parallel to the xy plane.

Therefore, in order to keep the engagement of the circuit substrate 406 and the stay 405 against the force parallel to the xy plane, additional fixation is normally performed. The circuit substrate 406 is fixed to the stay 405 by using, for example, screwing, pinning, brazing, soldering, an adhesive, strong adhesive tape, or the like. Such additional fixation not only increases the number of steps of attaching the circuit substrate 406 to the liquid crystal display panel 2 but also further increases a thickness of a space necessary for arrangement of the circuit substrate 6. In particular, when screwing is used, a thickness of a head of a screw and a thickness of a nut that receives a tip of the screw remarkably increase the thickness of the space necessary for arrangement of the circuit substrate 6.

Accordingly, as a result of comparison of FIGS. 8(a) and 8(b), the liquid crystal display module 1 according to Embodiment 1 exerts an advantageous effect as follows.

First, the thickness D1 of the overlap according to Embodiment 1 is able to be reduced as compared to the thickness D41 of the overlap in the comparative example. That is, the thickness of the space necessary for arrangement of the circuit substrate 6 is able to be reduced. As a result, a thickness of a frame of the liquid crystal display module 1 is able to be reduced.

Secondly, the engagement of the circuit substrate 6 and the stay 5 according to Embodiment 1 is able to be kept stably and easily as compared to the engagement of the circuit substrate 406 and the stay 405 in the comparative example. Thus, additional fixation (for example, fixation using screwing, pinning, brazing, soldering, an adhesive, strong adhesive tape, or the like) for stabilizing the engagement is not necessary. As a result, the number of steps of assembling the liquid crystal display module 1 according to Embodiment 1 is able to be reduced as compared to the number of steps of assembling the liquid crystal display module 401 of the comparative example. Further, it is possible to avoid an increase of the thickness of the space necessary for arrangement of the circuit substrate 6, which is caused by additional fixation.

### (Assembling Step)

The liquid crystal display module 1 is assembled as follows, for example.

First, the followings are prepared.
On the circuit substrate 6, the notch portion 66 is provided and the connector 9, and, as necessary, a control circuit or the like are mounted.
The stay 5 is cut out from the bezel 4.
The backlight 3, the liquid crystal display panel 2 in which the liquid crystal 22 is sealed by the sealant 24 between the facing substrate 21 and the matrix substrate 23, the flexible substrate 7, and the protection tape 8 are prepared.

Then, one end of the flexible substrate 7 is connected to the liquid crystal display panel 2 and the other end thereof is connected to the circuit substrate 6. Thereby, the circuit substrate 6 is connected to the liquid crystal display panel 2 through the flexible substrate 7 (connection step).

Subsequently, the bezel 4 is attached to the backlight 3 and the liquid crystal display panel 2 is attached to the backlight 3 (second engagement step). Then, the fitting portion 54 of the stay 5 is fitted into the inside of the notch portion 66 of the circuit substrate 6 so that the circuit substrate 6 and the overlapping portion 52 of the stay 5 are engaged (first engagement step). Thereby, the circuit substrate 6 is attached to the liquid crystal display panel 2 through the stay 5 and the bezel 4 (attachment step).

Then, the protection tape 8 is put on the surfaces of the circuit substrate 6 and the stay 5 to protect the surface of the circuit substrate 6 and further stabilize engagement of the circuit substrate 6 and the stay 5.

### Effect

According to the foregoing description, the liquid crystal display module 1 (liquid crystal display device) is configured to include: the liquid crystal display panel 2 (display panel) provided with the display screen 25; the circuit substrate 6 provided with the notch portion 66; the flexible substrate 7 (wiring portion) that connects the circuit substrate 6 with the liquid crystal display panel 2; and the bezel 4 and the stay 5 (holding structure) by which the circuit substrate 6 is attached to the liquid crystal display panel 2. Further, the stay 5 includes the overlapping portion 52 (first engagement portion), and the overlapping portion 52 includes the fitting portion 54 capable of being fitted into the inside of the notch portion 66 and is able to be engaged with the circuit substrate 6. Moreover, the bezel 4 (second engagement portion) is configured to enable engagement with the liquid crystal display panel 2.

According to the aforementioned configuration, the fitting portion 54 is able to be fitted into the inside of the notch portion 66. Thus, in a state where the overlapping portion 52 is engaged with the circuit substrate 6, the thickness D1 of overlap of the circuit substrate 6 and the overlapping portion 52 is smaller than the sum of the thickness D2 of the circuit substrate 6 and the thickness D3 of the overlapping portion 52 by at least a thickness D4 of the fitting portion 54. Accordingly, by keeping the thickness D2 of the circuit substrate 6 and the thickness D3 of the overlapping portion 52, a mechanical intensity of the circuit substrate 6 and the overlapping portion 52 of the stay 5 is able to be easily kept, and by reducing the thickness D1 of overlap of the circuit substrate 6 and the overlapping portion 52, the thickness of the space necessary for arrangement of the circuit substrate 6 is able to be reduced.

Moreover, the configuration of the liquid crystal display module 1 may be a configuration in which the stay 5 and the bezel 4 are set so that a whole or only a part of the overlapping portion 52 is positioned inside the circuit substrate 6 in plan view from the z axis direction.

According to the aforementioned configuration, the whole or only the part of the overlapping portion 52 is overlapped with the circuit substrate 6 and the other part (specifically, the connection portion 53 and the bezel 4) is not overlapped with the circuit substrate 6. Thus, a thickness of the other part does not affect the thickness of the space necessary for arrangement of the circuit substrate 6.

Moreover, the configuration of the liquid crystal display module 1 may be a configuration in which the overlapping portion 52 includes the non-fitting portion 55 that is positioned outside the notch portion 66 when the fitting portion 54 is fitted into the inside of the notch portion 66.

According to the aforementioned configuration, the overlapping portion 52 includes the fitting portion 54 and the non-fitting portion 55. Thus, the thickness D1 of the overlapping portion 52 is able to be made larger than the thickness D4 of the fitting portion 54, that is, a depth of the notch portion 66. More preferably, the configuration may be such that the outer circumference of the non-fitting portion 55 is matched with the outer circumference of the fitting portion 54 in plan view from the z axis direction.

Moreover, the configuration of the liquid crystal display module 1 may be a configuration in which the circuit substrate 6 is positioned in a direction parallel to the xy plane relatively to the liquid crystal display panel 2; and the notch portion 66 communicates with the side surface 62 of the circuit substrate 6, which is opposed to the liquid crystal display panel 2.

According to the aforementioned configuration, the notch portion 66 communicates with the side surface 62 of the circuit substrate 6, which is opposed to the liquid crystal display panel 2. Thus, the stay 5 is able to linearly extend from the liquid crystal display panel 2 toward the circuit substrate 6 so as to cross the side surface 62 in plan view from the z axis direction.

Moreover, the configuration of the liquid crystal display module 1 may be a configuration in which the stay 5 further includes the connection portion 53 that connects the overlapping portion 52 and the bezel 4; and the thickness of the overlapping portion 52 is equal to or more than a thickness of the connection portion 53.

According to the aforementioned configuration, the thickness of the overlapping portion 52 is equal to or more than the thickness of the connection portion 53. Thus, a mechanical intensity of the overlapping portion 52 is able to be easily made equal to or more than a mechanical intensity of the connection portion.

Moreover, the configuration of the liquid crystal display module 1 may be a configuration in which the notch portion 66 and the fitting portion 54 are able to be meshed with each other.

According to the aforementioned configuration, the notch portion 66 and the fitting portion 54 are able to be meshed with each other. The mesh enables to stabilize engagement of the circuit substrate 6 and the overlapping portion 52. More preferably, the notch portion 66 and the fitting portion 54 may be able to be meshed with each other so as to resist a mechanical force applied to the circuit substrate 6.

For example, the configuration of the liquid crystal display module 1 is more preferably a configuration in which the connector 9 is mounted on the circuit substrate 6 and the notch portion 66 and the fitting portion 54 are able to be meshed with each other so as to resist the mechanical force in a direction in which the connector 9 is inserted or removed.

In this case, fitting of the notch portion 66 and the fitting portion 54 resists the mechanical force in the direction in which the connector 9 is inserted or removed. Thus, the engagement of the circuit substrate 6 and the overlapping portion 52 is able to be stabilized against the mechanical force in the direction in which the connector 9 is inserted or removed.

Specifically, the direction in which the connector 9 is inserted or removed may be a direction parallel to the xy plane and is more preferably a direction parallel to the x axis direction in which the circuit substrate 6 is positioned with respect to the liquid crystal display panel 2.

Moreover, the configuration of the liquid crystal display module 1 may be a configuration in which the liquid crystal display module 1 further includes the backlight 3; and the circuit substrate 6 is attached to the liquid crystal display panel 2 through the stay 5, the bezel 4, and the backlight 3.

According to the aforementioned configuration, the circuit substrate 6 is able to be indirectly attached to the liquid crystal display panel 2 through the backlight 3.

Moreover, the configuration of the liquid crystal display module 1 may be a configuration in which the overlapping portion 52 is engaged with the circuit substrate 6 (i) when the fitting portion 54 is fitted into the inside of the notch portion 66 and (ii) when the protection tape 8 (surface protection tape) that protects the surface of the circuit substrate 6 is bonded integrally to the surfaces of the stay 5 and the circuit substrate 6.

According to the aforementioned configuration, the engagement of the stay 5 and the circuit substrate 6 is sufficiently stabilized by the fitting of the fitting portion 54 and the notch portion 66 and the bonding by the protection tape 8. This makes it possible not to require additional fixation for further stabilizing the engagement. When additional fixation is not performed, the number of manufacturing steps of manufacturing the liquid crystal display module 1 is able to be reduced, and further, an increase of the thickness of the space necessary for arrangement of the circuit substrate 6, which is caused by the additional fixation, is able to be avoided.

A manufacturing method of the liquid crystal display module 1 may be a method including: a connection step of connecting the circuit substrate 6, which is provided with the notch portion 66, with the liquid crystal display panel 2, which is provided with the display screen 25, through the flexible substrate 7 (wiring portion); and an attachment step of attaching the circuit substrate 6 to the liquid crystal display panel 2 through the bezel 4 and the stay 5 (holding structure), and the attachment step includes: a first engagement step of causing the fitting portion 54 provided in the overlapping portion 52 (first engagement portion) of the stay 5 to be fitted into the inside of the notch portion 66 and causing the overlapping portion 52 to be engaged with the circuit substrate 6; and a second engagement step of causing the bezel 4 (second engagement portion) to be engaged with the liquid crystal display panel 2.

According to the aforementioned method, the configuration of the liquid crystal display module 1 as described above is able to be achieved. Thus, by keeping the thickness D2 of the circuit substrate 6 and the thickness D3 of the overlapping portion 52, the mechanical intensity of the circuit substrate 6 and the overlapping portion 52 of the stay 5 is able to be easily kept, and by reducing the thickness D1 of overlap of the circuit substrate 6 and the overlapping portion 52, the thickness of the space necessary for arrangement of the circuit substrate 6 is able to be reduced.

### Embodiment 2

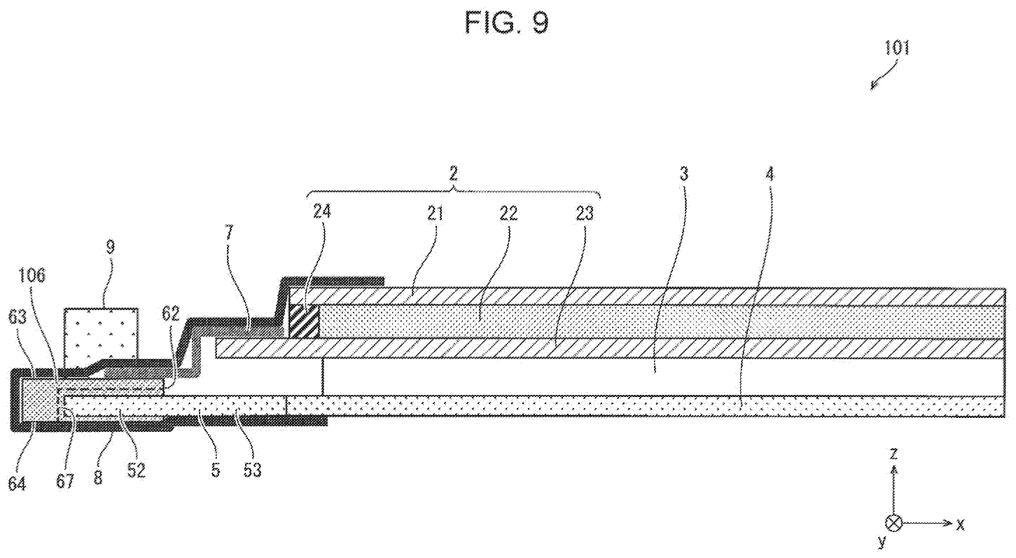

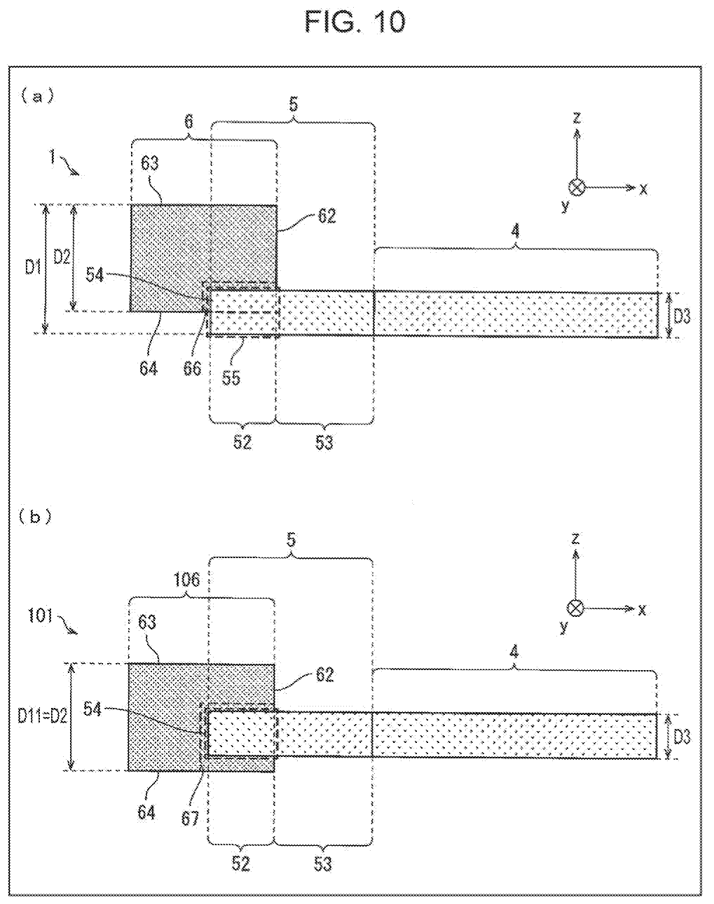

Another embodiment of the invention will be described as follows with reference to FIGS. 9 and 10. Note that, for convenience of description, a member having the same function as that of the member described in the aforementioned embodiment will be given the same reference sign and description thereof will be omitted.

### (Liquid Crystal Display Module)

FIG. 9 is a sectional view illustrating a schematic configuration of an end of a liquid crystal display module 101 according to Embodiment 2 of the invention.

As illustrated in FIG. 9, the liquid crystal display module 101 according to Embodiment 2 includes the liquid crystal display panel 2, the backlight 3, the bezel 4, the stay 5, the flexible substrate 7, and the protection tape 8, similarly to the liquid crystal display module 1 according to Embodiment 1 described above. The liquid crystal display module 101 according to Embodiment 2 is different from the liquid crystal display module 1 according to Embodiment 1 and includes a circuit substrate 106 provided with a notch portion 67.

The liquid crystal display module 101 according to Embodiment 2 is different from the liquid crystal display module 1 according to Embodiment 1 described above only in that the notch portion 67 according to Embodiment 2 is deeper than the notch portion 66 according to Embodiment 1 described above. More specifically, while the depth of the notch portion 66 according to Embodiment 1 described above is smaller than the thickness D3 of the overlapping portion 52 of the stay 5, a thickness of the notch portion 67 according to Embodiment 2 is larger than the thickness D3 of the overlapping portion 52 of the stay 5.

### (Comparison)

FIG. 10(a) is a sectional view illustrating the circuit substrate 6 and the stay 5 that are illustrated in FIG. 1 and FIG. 10(b) is a sectional view illustrating the circuit substrate 106 and the stay 5 that are illustrated in FIG. 9, and FIGS. 10(a) and 10(b) are views for comparing both of them.

As illustrated in FIG. 10(a), in the liquid crystal display module 1 according to Embodiment 1 described above, the overlapping portion 52 is constituted by the fitting portion 54 that is able to be fitted into the inside of the notch portion 66 and the non-fitting portion 55 that is not able to be fitted. Meanwhile, as illustrated in FIG. 10(b), in the liquid crystal display module 101 according to Embodiment 2, the overlapping portion 52 is constituted by only the fitting portion 54 that is able to be fitted into an inside of the notch portion 67. Thus, a thickness D11 of overlap of the circuit substrate 106 according to Embodiment 2 and the stay 5 is smaller than the thickness D1 of overlap of the circuit substrate 6 according to Embodiment 1 described above and the stay 5.

Accordingly, the liquid crystal display module 101 according to Embodiment 2 is able to further reduce a thickness of a space necessary for arrangement of the circuit substrate 106 as compared to the liquid crystal display module 1 according to Embodiment 1 described above.

### Effect

According to the foregoing description, the liquid crystal display module 101 according to Embodiment 2 is able to exert an effect similar to that of the liquid crystal display module 1 according to Embodiment 1 described above.

Moreover, a configuration of the liquid crystal display module 101 may be a configuration in which a whole of the overlapping portion 52 is the fitting portion 54.

According to the aforementioned configuration, the whole of the overlapping portion 52 is the fitting portion 54. Thus, in a state where the overlapping portion 52 is engaged with the circuit substrate 6, the thickness D11 of overlap of the circuit substrate 106 and the overlapping portion 52 is equal to the thickness D2 of the circuit substrate 6. Accordingly, it is possible to further reduce the thickness of the space necessary for arrangement of the circuit substrate 106.

### Embodiment 3

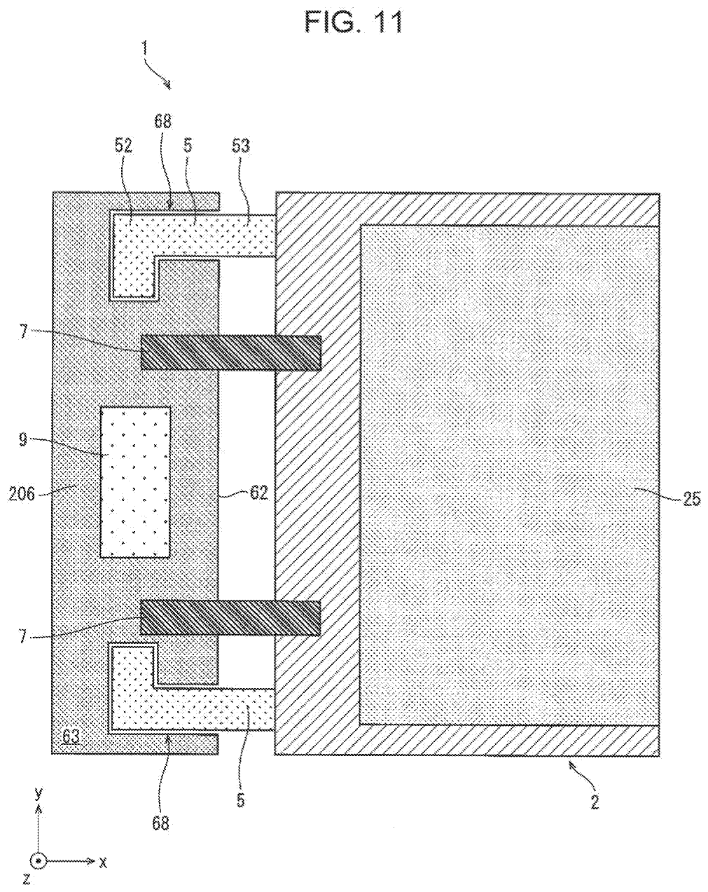

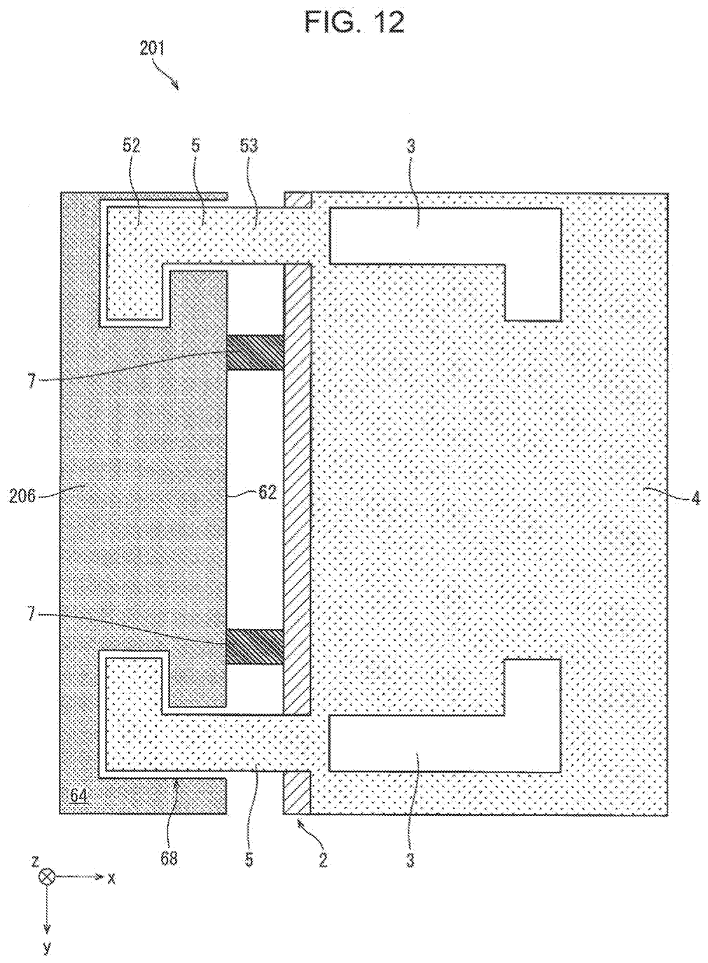

Another embodiment of the invention will be described as follows with reference to FIGS. 11 and 12. Note that, for convenience of description, a member having the same function as that of the member described in the aforementioned embodiments will be given the same reference sign and description thereof will be omitted.

### (Liquid Crystal Display Module)

FIG. 11 is a top view illustrating a schematic configuration of an end of a liquid crystal display module 201 according to Embodiment 3 of the invention. FIG. 12 is a bottom view illustrating the schematic configuration of the end of the liquid crystal display module 201 illustrated in FIG. 11. Note that, for convenience of illustration, the protection tape 8 is omitted in FIGS. 11 and 12.

As illustrated in FIGS. 11 and 12, the liquid crystal display module 201 according to Embodiment 3 includes the liquid crystal display panel 2, the backlight 3, the bezel 4, the stay 5, the flexible substrate 7, and the protection tape 8, similarly to the liquid crystal display modules 1 and 101 according to Embodiments 1 and 2 described above. The liquid crystal display module 201 according to Embodiment 3 is different from the liquid crystal display modules 1 and 101 according to Embodiments 1 and 2 described above and includes a circuit substrate 206 provided with a notch portion 68.

The liquid crystal display module 201 according to Embodiment 3 is different from the liquid crystal display modules 1 and 101 according to Embodiments 1 and 2 described above only in that the notch portion 68 according to Embodiment 3 is penetrated between the upper surface 63 and the lower surface 64 of the circuit substrate 206 in the z axis direction. Thus, the overlapping portion 52 of the stay 5 is seen from above the circuit substrate 206 as illustrated in FIG. 11.

The notch portion 68 that penetrates is preferable because of being formed more easily than the notch portion 66 or 62 that does not penetrate. In a case where a thickness D2 of the circuit substrate 206 is equal to or less than the thickness D3 of the overlapping portion 52 of the stay 5, a thickness of overlap of the circuit substrate 206 according to Embodiment 3 and the stay 5 is able to be made equal to the thickness D2 of the circuit substrate 206, so that the notch portion 68 is preferable.

Note that, strictly speaking, the overlapping portion 52 is not overlapped with the circuit substrate 206 in Embodiment 3. Thus, the stay 5 is not overlapped with the circuit substrate 206 and is positioned only outside the circuit substrate 206. Moreover, the overlapping portion 52 may include or may not include the non-fitting portion 55.

In addition, the notch portion 68 may penetrate not entirely but partially. In a case of partial penetration, a part of the overlapping portion 52 is overlapped with the circuit substrate 206.

### Effect

According to the foregoing description, the liquid crystal display module 201 according to Embodiment 3 is able to exert an effect similar to those of the liquid crystal display modules 1 and 101 according to Embodiments 1 and 2 described above.

Moreover, the configuration of the liquid crystal display module 1 may be a configuration in which the stay 5 and the bezel 4 are positioned only outside the circuit substrate 206 in plan view from the z axis direction.

According to the aforementioned configuration, a part (specifically, the connection portion 53 and the bezel 4) other than the overlapping portion 52 is not overlapped with the circuit substrate 206. Accordingly, a thickness of the other part does not affect a thickness of a space necessary for arrangement of the circuit substrate 206.

Moreover, the configuration of the liquid crystal display module 101 may be a configuration in which the notch portion 68 is provided so as to penetrate the circuit substrate 206 in the z axis direction.

According to the aforementioned configuration, the notch portion 68 penetrates the circuit substrate 206. Thus, the notch portion 68 is able to be formed more easily than the notch portion 66 or 62 that does not penetrate. Further, in a case where the thickness D2 of the circuit substrate 206 is equal to or less than the thickness D3 of the overlapping portion 52 of the stay 5, the thickness of overlap of the circuit substrate 206 according to Embodiment 3 and the stay 5 is able to be made equal to the thickness D2 of the circuit substrate 206.

### Embodiment 4

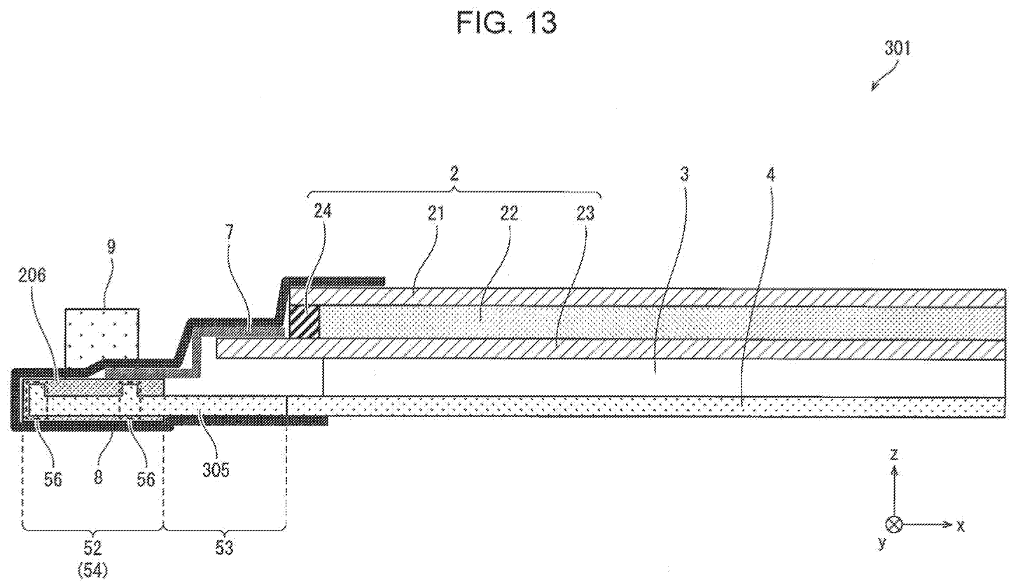

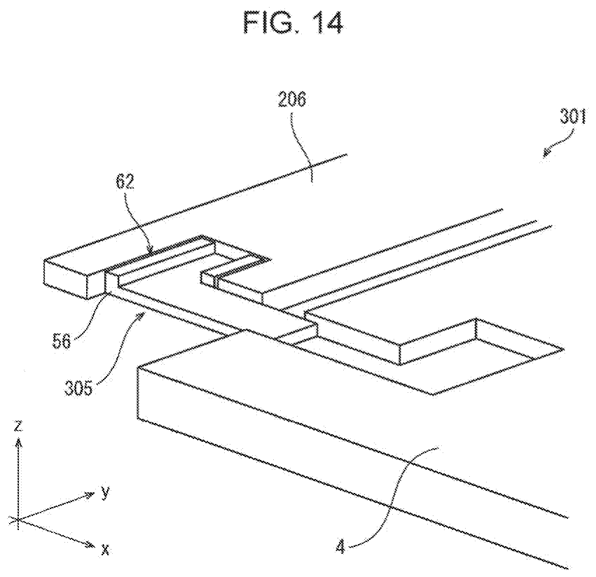

Another embodiment of the invention will be described as follows with reference to FIGS. 13 and 14. Note that, for convenience of description, a member having the same function as that of the member described in the aforementioned embodiments will be given the same reference sign and description thereof will be omitted.

### (Liquid Crystal Display Module)

FIG. 13 is a sectional view illustrating a schematic configuration of an end of a liquid crystal display module 301 according to Embodiment 4 of the invention. FIG. 14 is a perspective view illustrating a schematic configuration of a corner of the liquid crystal display module 301 illustrated in FIG. 13. Note that, for convenience of illustration, the protection tape 8 is omitted in FIG. 14.

As illustrated in FIG. 13, the liquid crystal display module 301 according to Embodiment 4 includes the liquid crystal display panel 2, the backlight 3, the bezel 4, the circuit substrate 206, the flexible substrate 7, and the protection tape 8, similarly to the liquid crystal display module 201 according to Embodiment 3 described above. The liquid crystal display module 301 according to Embodiment 4 is different from the liquid crystal display module 201 according to Embodiment 3 described above and includes a stay 305 provided with a thickened portion 56.

The liquid crystal display module 301 according to Embodiment 4 is different from the liquid crystal display module 201 according to Embodiment 3 described above only in that the thickened portion 56 is provided in the overlapping portion 52 of the stay 305.

### (Thickened Portion)

The thickened portion 56 increases an effective thickness of the fitting portion 54 while suppressing an increase of a weight of the overlapping portion 52 as compared to a case where the fitting portion 54 is entirely thickened. Specifically, the thickened portion 56, which is thicker than the other part of the fitting portion 54, is formed so as to face an outer circumference of the overlapping portion 52. Thus, the thickened portion 56 enables to more reliably fit the fitting portion 54 and the notch portion 68.

A plate member (for example, metal plate) by which the stay 305 is formed is normally thinner than the circuit substrate 206. Thus, in a case where the thickened portion 56 is not provided, the fitting portion 54 is easily removed from the notch portion 68 in some cases. On the other hand, the stay 305 according to Embodiment 4 includes the thickened portion 56. Thus, the fitting portion 54 of the stay 305 has the large effective thickness, and is thus difficult to be removed from the notch portion 68. Accordingly, the thickened portion 56 is preferably formed so as to face the outer circumference of the overlapping portion 52.

Further, the thickened portion 56 enables to increase an area of opposed surfaces of the fitting portion 54 and the notch portion 68. Thus, it is possible to increase resistance against the mechanical force caused by insertion/removal of the connector 9 and also possible to increase electrical connection between the stay 305 and the circuit substrate 206. As a result, engagement of the circuit substrate 206 and the stay 305 is further stabilized and electrical unity is also enhanced.

The thickened portion 56 may be formed in any manner as long as increasing the thickness of the overlapping portion 52 of the stay 305. For example, the thickened portion 56 may be formed by applying bending processing or drawing processing to the stay 305 in a flat state.

Note that, though the circuit substrate 206 provided with the notch portion 68 that penetrates is used in the configuration illustrated in FIG. 14, the circuit substrate 6 or 106 provided with the notch portion 66 or 62 that does not penetrate may be used. Further, in the configuration illustrated in FIG. 14, the overlapping portion 52 does not include the non-fitting portion 55, but may include the non-fitting portion 55.

### Effect

According to the foregoing description, the liquid crystal display module 301 according to Embodiment 4 is able to exert an effect similar to those of the liquid crystal display modules 1, 101, and 201 according to Embodiments 1 to 3 described above.

Moreover, the configuration of the liquid crystal display module 301 may be a configuration in which the fitting portion 54 includes the thickened portion 56, which is thicker than the other part of the fitting portion 54, so that the thickened portion 56 faces the outer circumference of the fitting portion 54.

According to the aforementioned configuration, the fitting portion 54 includes the thickened portion 56, which is thicker than the other part, so that the thickened portion 56 faces the outer circumference of the fitting portion 54. Thus, the thickened portion 56 is able to increase the effective thickness of the fitting portion 54 while suppressing an increase of the weight of the overlapping portion 52 as compared to a case where the fitting portion 54 is entirely thickened. As a result, the thickened portion 56 enables to more reliably fit the fitting portion 54 and the notch portion 68.

Moreover, by increasing the effective thickness of the fitting portion 54, the thickened portion 56 is able to increase the area of the opposed surfaces of the fitting portion 54 and the notch portion 68. Thus, the thickened portion 56 is able to increase resistance against the mechanical force caused by insertion/removal of the connector 9 and also increase electrical connection between the stay 305 and the circuit substrate 206. As a result, engagement of the circuit substrate 206 and the stay 305 is able to be further stabilized and electrical unity is also able to be enhanced.

### CONCLUSION

A display device (liquid crystal display module 1, 101, 201, 301) according to an aspect 1 of the invention includes: a display panel (liquid crystal display panel 2) provided with a display screen (25); a circuit substrate (6, 106, 206) provided with a notch portion (66, 67, 68); a wiring portion (flexible substrate 7) that connects the circuit substrate (6, 106, 206) with the display panel (2); and a holding structure (bezel 4 and stay 5) by which the circuit substrate (6, 106, 206) is attached to the display panel (2), in which the holding structure (bezel 4 and stay 5, 305) includes a first engagement portion (overlapping portion 52) that includes a fitting portion (54) capable of being fitted into an inside of the notch portion (66, 67, 68) and is able to be engaged with the circuit substrate (6, 106, 206); and a second engagement portion (bezel 4) that is different from the first engagement portion (overlapping portion 52) and is able to be engaged with the display panel (2).

According to the aforementioned configuration, the fitting portion of the first engagement portion of the holding structure is able to be fitted into the inside of the notch portion of the circuit substrate. Thus, in a state where the first engagement portion is engaged with the circuit substrate, a thickness of overlap of the circuit substrate and the holding structure is smaller than a sum of a thickness of the circuit substrate and a thickness of the holding structure by at least a thickness of the fitting portion. Accordingly, by keeping the thickness of the circuit substrate and the thickness of the first engagement portion, a mechanical intensity of the circuit substrate and the first engagement portion is able to be easily kept, and by reducing the thickness of overlap of the circuit substrate and the first engagement portion, a thickness of a space necessary for arrangement of the circuit substrate is able to be reduced.

The display device (liquid crystal display module 1, 101, 201, 301) according to an aspect 2 of the invention may have a configuration in which the holding structure (bezel 4 and stay 5) is provided so that a whole of the holding structure is positioned only outside the circuit substrate (206) or a whole or only a part of the first engagement portion (overlapping portion 52) is positioned inside the circuit substrate (6, 106) in plan view from a direction (z axis direction) vertical to the display screen (25), in the aspect 1.

According to the aforementioned configuration, a part other than the first engagement portion is not overlapped with the circuit substrate. Accordingly, a thickness of the other part does not affect the thickness of the space necessary for arrangement of the circuit substrate.

The display device (liquid crystal display module 101, 201, 301) according to an aspect 3 of the invention may have a configuration in which a whole of the first engagement portion (overlapping portion 52) is the fitting portion (54), in the aspect 1 or 2.

According to the aforementioned configuration, the whole of the first engagement portion is the fitting portion. Thus, in the state where the first engagement portion is engaged with the circuit substrate, the thickness of overlap of the circuit substrate and the overlapping portion is equal to the thickness of the circuit substrate. Accordingly, it is possible to further reduce the thickness of the space necessary for arrangement of the circuit substrate.

The display device (liquid crystal display module 1) according to an aspect 4 of the invention may have a configuration in which the first engagement portion (overlapping portion 52) includes a non-fitting portion (55) that is positioned outside the notch portion (66) when the fitting portion (54) is fitted into the inside of the notch portion (66), in the aspect 1 or 2.

According to the aforementioned configuration, the overlapping portion includes the fitting portion and the non-fitting portion. Thus, the thickness of the overlapping portion is able to be made larger than the thickness of the fitting portion, that is, a depth of the notch portion. More preferably, the configuration may be such that an outer circumference of the non-fitting portion is matched with an outer circumference of the fitting portion in plan view from the direction vertical to the display screen.

The display device (liquid crystal display module 1, 101, 201, 301) according to an aspect 5 of the invention may have a configuration in which the circuit substrate (6, 106, 206) is positioned in a direction (x axis direction) parallel to the display screen (25) relatively to the display panel (2), and the notch portion (66, 67, 68) communicates with a side surface 62 of the circuit substrate, which is opposed to the display panel, in any one of the aspects 1 to 4.

According to the aforementioned configuration, the notch portion communicates with the side surface of the circuit substrate, which is opposed to the display panel. Thus, the stay is able to linearly extend from the display panel toward the circuit substrate so as to cross the side surface in plan view from the direction vertical to the display screen.

The display device (liquid crystal display module 1, 101, 201, 301) according to an aspect 6 of the invention may have a configuration in which the holding structure (stay 5, 305) further includes a connection portion (53) that connects the first engagement portion (overlapping portion 52) and the second engagement portion (bezel 4), and a thickness of the first engagement portion is equal to or more than a thickness of the connection portion, in any one of the aspects 1 to 5.

According to the aforementioned configuration, the thickness of the first engagement portion is equal to or more than the thickness of the connection portion. Thus, a mechanical intensity of the first engagement portion is able to be easily made equal to or more than a mechanical intensity of the connection portion.

The display device (liquid crystal display module 1, 101, 201, 301) according to an aspect 7 of the invention may have a configuration in which the notch portion (66, 67, 68) and the fitting portion (54) are able to be meshed with each other, in any one of the aspects 1 to 6.

According to the aforementioned configuration, the notch portion and the fitting portion are able to be meshed with each other. The mesh enables to stabilize engagement of the substrate and the first engagement portion. More preferably, the notch portion and the fitting portion may be able to be meshed with each other so as to resist a mechanical force applied to the circuit substrate.

The display device (liquid crystal display module 1, 101, 201, 301) according to an aspect 8 of the invention may have a configuration in which a connector (9) is mounted on the circuit substrate (6, 106, 206), and the notch portion (66, 67, 68) and the fitting portion (54) are able to be meshed with each other so as to resist a mechanical force in a direction in which the connector (9) is inserted or removed, in the aspect 7.

According to the aforementioned configuration, the fitting of the notch portion and the fitting portion resists against the mechanical force in the direction in which the connector 9 is inserted or removed. Thus, the engagement of the circuit substrate and the first engagement portion is able to be stabilized against the mechanical force in the direction in which the connector is inserted or removed.

The display device (liquid crystal display module 1, 101, 201, 301) according to an aspect 9 of the invention may have a configuration in which the direction in which the connector (9) is inserted or removed is a direction (x axis direction) parallel to the display screen (25), in the aspect 8.

The display device (liquid crystal display module 201, 301) according to an aspect 10 of the invention may have a configuration in which the notch portion (68) is provided so as to penetrate the circuit substrate (206) in a direction (z axis direction) vertical to the display screen (25), in any one of the aspects 1 to 9.

According to the aforementioned configuration, the notch portion penetrates the circuit substrate. Thus, the notch portion is able to be formed more easily than a notch portion that does not penetrate. Further, in a case where the thickness of the circuit substrate is equal to or less than the thickness of the first engagement portion, the thickness of overlap of the circuit substrate and the first engagement portion is able to be made equal to the thickness of the circuit substrate.

The display device (liquid crystal display module 301) according to an aspect 11 of the invention may have a configuration in which the fitting portion (54) includes a thickened portion, which is thicker than the other part of the fitting portion (54), so that the thickened portion faces an outer circumference of the fitting portion (54), in any one of the aspects 1 to 10.

According to the aforementioned configuration, the fitting portion includes the thickened portion, which is thicker than the other part, so that the thickened portion faces the outer circumference of the fitting portion. Thus, the thickened portion is able to increase an effective thickness of the fitting portion while suppressing an increase of a weight of the overlapping portion as compared to a case where the fitting portion is entirely thickened. As a result, the thickened portion enables to more reliably fit the fitting portion and the notch portion.

Moreover, by increasing the effective thickness of the fitting portion, the thickened portion is able to increase an area of opposed surfaces of the fitting portion and the notch portion. Thus, the thickened portion is able to increase resistance against the mechanical force caused by insertion/removal of the connector and also increase electrical connection between the holding structure and the substrate. As a result, engagement of the holding structure and the substrate is able to be further stabilized and electrical unity between the holding structure and the substrate is also able to be enhanced.

The display device (liquid crystal display module 1, 101, 201, 301) according to an aspect 12 of the invention may have a configuration in which the display device further includes a backlight (3) and the circuit substrate (6, 106, 206) is attached to the display panel (2) through the holding structure (stay 5, 305 and bezel 4) and the backlight (3), in any one of the aspects 1 to 11.

According to the aforementioned configuration, the circuit substrate is able to be indirectly attached to the liquid crystal display panel 2 through the backlight.

The display device (liquid crystal display module 1, 101, 201, 301) according to an aspect 13 of the invention may have a configuration in which the first engagement portion (overlapping portion 52) is engaged with the circuit substrate (i) when the fitting portion (54) is fitted into the inside of the notch portion (66, 67, 68) and (ii) when surface protection tape (8) that protects a surface of the circuit substrate 6 is bonded integrally to surfaces of the holding structure (stay 5, 305) and the circuit substrate (6, 106, 206), in any one of the aspects 1 to 12.

According to the aforementioned configuration, the engagement of the first engagement portion and the circuit substrate is sufficiently stabilized by the fitting of the fitting portion and the notch portion and the bonding by the surface protection tape. This makes it possible not to require additional fixation for further stabilizing the engagement. When additional fixation is not performed, the number of manufacturing steps of manufacturing the display device is able to be reduced, and further, an increase of the thickness of the space necessary for arrangement of the circuit substrate, which is caused by the additional fixation, is able to be avoided.

A manufacturing method of a display device (liquid crystal display module 1, 101, 201, 301) according to an aspect 14 of the invention includes the steps of: connecting a circuit substrate (6, 106, 206), which is provided with a notch portion (66, 67, 68), with a display panel (liquid crystal display panel 2), which is provided with a display screen (25), through a wiring portion (flexible substrate 7); and attaching the circuit substrate (6, 106, 206) to the display panel (2) through the holding structure (bezel 4 and stay 5), in which the attaching includes causing a fitting portion (54) provided in a first engagement portion (overlapping portion 52) of the holding structure to be fitted into an inside of the notch portion (66, 67, 68) and causing the first engagement portion (overlapping portion 52) to be engaged with the circuit substrate (6, 106, 206); and causing a second engagement portion (bezel 4) to be engaged with the display panel (2).

According to the aforementioned method, the display device in the aspect 1 is able to be manufactured. Thus, by keeping the thickness of the circuit substrate and the thickness of the first engagement portion, the mechanical intensity of the circuit substrate and the first engagement portion is able to be easily kept, and by reducing the thickness of overlap of the circuit substrate and the first engagement portion, the thickness of the space necessary for arrangement of the circuit substrate is able to be reduced.

The invention is not limited to each of the embodiments described above, and may be modified in various manners within the scope indicated in the claims and an embodiment achieved by appropriately combining technical means disclosed in each of different embodiments is also included in the technical scope of the invention. Further, by combining the technical means disclosed in each of the embodiments, a new technical feature may be formed.

### REFERENCE SIGNS LIST

1, 101, 101, 201, 301, 401 liquid crystal display module (display device)
2 liquid crystal display panel (display panel)
3 backlight
4 backlight rear bezel, bezel (holding structure, second engagement portion)
5, 305, 405 stay (holding structure)
6, 106, 106, 206, 406 circuit substrate
7 flexible substrate (wiring portion)
8 protection tape (surface protection tape)
9 connector
21 facing substrate
23 matrix substrate
22 liquid crystal
24 sealant
25 display screen
52 overlapping portion (first engagement portion)
53 connection portion
54 fitting portion
55 non-fitting portion
56 thickened portion
62 side surface
63 upper surface
64 lower surface
66, 67, 68 notch portion
D1, D11, D41 thickness of overlap of circuit substrate and overlapping portion (first engagement portion)
D2, D42 thickness of circuit substrate
D3, D43 thickness of overlapping portion (first engagement portion)
D4 thickness of fitting portion

1. A display device comprising:
a display panel provided with a display screen;
a circuit substrate provided with a notch portion;
a wiring portion that connects the circuit substrate with the display panel; and
a holding structure by which the circuit substrate is attached to the display panel, wherein
the holding structure includes
a first engagement portion that includes a fitting portion capable of being fitted into an inside of the notch portion and is able to be engaged with the circuit substrate, and
a second engagement portion that is different from the first engagement portion and is able to be engaged with the display panel.

2. The display device according to claim 1, wherein
the holding structure is provided so that
a whole of the holding structure is positioned only outside the circuit substrate or
a whole or only a part of the first engagement portion is positioned inside the circuit substrate in plan view from a direction vertical to the display screen.

3. The display device according to claim 2, wherein a whole of the first engagement portion is the fitting portion.

4. The display device according to claim 2, wherein the first engagement portion includes a non-fitting portion that is positioned outside the notch portion when the fitting portion is fitted into the inside of the notch portion.

5. The display device according to claim 3, wherein
the circuit substrate is positioned in a direction parallel to the display screen relatively to the display panel, and
the notch portion communicates with a side surface of the circuit substrate, which is opposed to the display panel.

6. The display device according to claim 1, wherein
the holding structure further includes a connection portion that connects the first engagement portion and the second engagement portion, and
a thickness of the first engagement portion is equal to or more than a thickness of the connection portion.

7. The display device according to claim 1, wherein the notch portion and the fitting portion are able to be meshed with each other.

8. The display device according to claim 7, wherein
a connector is mounted on the circuit substrate, and
the notch portion and the fitting portion are able to be meshed with each other so as to resist a mechanical force in a direction in which the connector is inserted or removed.

9. The display device according to claim 8, wherein the direction in which the connector is inserted or removed is a direction parallel to the display screen.

10. The display device according to claim 1, wherein the notch portion is provided so as to penetrate the circuit substrate in a direction vertical to the display screen.

11. The display device according to claim 1, wherein the fitting portion includes a thickened portion, which is thicker than the other part of the fitting portion, so that the thickened portion faces an outer circumference of the fitting portion.

12. The display device according to claim 1, further comprising a backlight, wherein
the circuit substrate is attached to the display panel through the holding structure and the backlight.

13. The display device according to claim 1, wherein the first engagement portion is engaged with the circuit substrate (i) when the fitting portion is fitted into the inside of the notch portion and (ii) when surface protection tape that protects a surface of the circuit substrate is bonded integrally to surfaces of the holding structure and the circuit substrate.

14. A manufacturing method of a display device, the method comprising the steps of:
connecting a circuit substrate, which is provided with a notch portion, with a display panel, which is provided with a display screen, through a wiring portion; and
attaching the circuit substrate to the display panel through the holding structure, wherein
the attaching includes
causing a fitting portion provided in a first engagement portion of the holding structure to be fitted into an inside of the notch portion and causing the first engagement portion to be engaged with the circuit substrate; and
causing a second engagement portion, which is different form the first engagement portion of the holding structure, to be engaged with the display panel.
